(19) United States
(12) Patent Application Publication
(10) Pub. No.: US 2007/0115016 A1
(43) Pub. Date: May 24, 2007

(54) Radio frequency identification tag with embedded memory testing scheme and the method of testing the same

(75) Inventors: Shao-Chang Chang, Taipei City (TW); Chien-Pin Lee, Luzhu Shiang (TW); Wen-Yuan Liu, Taoyuan City (TW)

Correspondence Address: BRUCE H. TROXELL, SUITE 1404, 5205 LEESBURG PIKE, FALLS CHURCH, VA, 22041, US

(73) Assignee: Industrial Technology Research Institute

(21) Appl. No.: 11/324,379

(22) Filed: Jan. 4, 2006

(30) Foreign Application Priority Data
Nov. 22, 2005 (TW) 094140889

(51) Int. Cl. G01R 31/02; G08B 13/14

(52) U.S. Cl. 324/763; 340/572.1

(57) ABSTRACT

A radio frequency identification (RFID) tag with embedded memory testing scheme and the method of testing the same is disclosed, in which the RFID tag is comprised of an analog block, a digital block and a memory block. Operationally, as the analog block receives and demodulates a memory self-test signal issued from a reader, the memory block is driven to issue a non-digital memory state signal to be received by the analog block where it is being converted into a digital memory state signal, and then the digital memory state signal is being transmitted to the digital block for enabling the same to make an evaluation to determine whether the received digital memory state signal fall within the range representing the memory is in good condition, and thereafter, the evaluation is send to the reader by the RFID tag so as to enable the reader to select a posterior process to be perform accordingly.

### FIELD OF THE INVENTION

The present invention relates to a radio frequency identification (RFID) tag with embedded memory testing scheme and the method of testing the same, and more particularly, to a RFID memory testing scheme capable of detecting and evaluating whether the memory embedded in a RFID tag is operating normally while issuing a memory state signal accordingly during the packaging and testing process of the RFID tag or during the operation of the RFID tag.

### BACKGROUND OF THE INVENTION

Radio frequency identification (RFID) is an automatic identification technology with ability to wireless communication (read and write data without direct contact) and without the necessity for line-of-sight, such that it is convenient, easy to use and well suited for automatic operation and can function under a variety of environment conditions while providing a high level of data integrity. RFID is a technology with bright future and is going to replace the conventional bar coding system for many companies and organizations are trying now to implement RFID in their infrastructure. RFID systems exist in countless variants, produced by many different manufacturers, but RFID system is mainly consists of RFID tags, readers and a computer system. RFID tag is a device capable of transmitting data to reader which is located on the object to be identified. Powering the RFID tags is important to any RFID system, and accordingly, there are three types of RFID tags which are active RFID tags, semi-active RFID tags and passive RFID tags. The active and semi-active RFID tags have no need to be powered by the reader. Active transponders have an integrated battery which supplies all or part of the needed power while enlarging the operational range of the same or enabling the RFID tag to record data detected by a sensor of the tag. Passive RFID tags do not have any integrated power source and therefore are totally dependent on reader's (magnetic/electrical) field to get the needed power supply. The passive RFID tag collects part of the energizing field via its antenna. Typically, passive RFID tags are smaller and lighter than active ones, and less expensive.

According to memory accessibility, there are two types of RFID tags: read-only tags and read/write tags, whereas most of the current RFID system have adopted the read/write RFID tags since they can be reprogrammed by reader's commands and thus are reusable and practical. Please refer to FIG. 1, which is a schematic diagram showing a conventional RFID tag. The RFID tag 1 of FIG. 1 is composed of an analog block 11, a digital block 12 and a memory block 13. As a command is received by the RFID tag 1, the analog block is enabled to perform a signal demodulation operation upon the received command and then transmit the demodulated command to the digital block 12 for enabling the same to perform a specific operation according to the demodulated command and thus issue a response accordingly while the memory block 13 storing the identification code (ID) of the RFIG tag 1 is being accessed or written-in with respect to the specific operation. Moreover, the response is being transmitted back to the analog block 11 through the transmission end (TXD) of the digital block 12 and then the analog block 11 is enabled to transmit the received response to a reader through an antenna attached to the RFID tag 1. It is common in a conventional RFID system that an operator can find the memory block of an RFID tag is damaged only when he/she is trying to access data from/write data into the same and the RFID tag with damaged memory must be identified and replaced otherwise the access/write-in operation can not be processed correctly. However, if a careless operator fails to identify and replace a RFID tag with damaged memory while interrogating the damaged RFID tag, the data accessed therefrom may be incorrect or the data to be written in to the RFID tag may fail such that not only the working efficiency and the readability of the RFID system are adversely affected, but worst of all, it might cause some disastrous economic loss.

From the above description, it is noted that a radio frequency identification (RFID) tag with embedded memory testing scheme is in great need for preventing a RFID system from the aforesaid loss by detecting and testing the status of the memories of its RFID tags before interrogating thereto.

### SUMMARY OF THE INVENTION

In view of the disadvantages of prior art, the primary object of the present invention is to provide a radio frequency identification (RFID) tag with embedded memory testing scheme and the method of testing the same, capable of detecting and evaluating whether the memory embedded in a RFID tag is operating normally while issuing a memory state signal accordingly.

To achieve the above object, the present invention provides a RFID tag with embedded memory testing scheme, comprising: an analog block, a digital block and a memory block; wherein, as the analog block receives and demodulates a memory self-test signal issued from a reader, the memory block is driven to issue a non-digital memory state signal to be received by the analog block where it is being converted into a digital memory state signal, and then the digital memory state signal is being transmitted to the digital block for enabling the same to make an evaluation to determine whether the received digital memory state signal fall within the range representing the memory is in good condition, and thereafter, the evaluation is send to the reader by the RFID tag so as to enable the reader to select a posterior process to be perform accordingly.

Preferably, the RFID tag can be an active/semi-active read/write RFID tag or a passive read/write RFID tag.

Preferably, the memory self-test signal received by the analog block is issued by a reader.

Preferably, the memory state signal issued by the memory block can be a current signal or a voltage signal.

Preferably, the analog block further comprises a band gap circuit, for converting a current memory state signal into a voltage memory state signal.

Preferably, the analog block further comprises an analog/digital (A/D) converter, for converting a voltage memory state signal into a digital memory state signal.

Preferably, the digital block further comprises a judge circuit, for making an evaluation to determine whether the received digital memory state signal fall within the range representing the memory is in good condition.

Preferably, the analog block further comprises a backscatter circuit, for transmitting the digital memory state signal to the reader by a means of backscattering.

To achieve the above object, the present invention provides a method for testing a RFID tag with embedded memory testing scheme, comprising steps of:
(a) providing a RFID tag comprising an analog block, a digital block and a memory block;
(b) enabling the RFID tag to receive a memory self-test signal issued by a reader;
(c) using the analog block to demodulate the received memory self-test signal so as to drive the memory block to issue a non-digital memory state signal;
(d) using the analog block to convert the non-digital memory state signal, being a voltage signal, into a digital memory state signal;
(e) using the digital block to make an evaluation for determining whether the received digital memory state signal fall within the range representing the memory is in good condition; and
(f) transmitting the evaluation to the reader by the RFID tag.

Preferably, the RFID tag can be an active/semi-active read/write RFID tag or a passive read/write RFID tag.

Preferably, the memory self-test signal received by the analog block is issued by a reader.

Preferably, the memory state signal issued by the memory block can be a current signal or a voltage signal.

Preferably, the analog block further comprises a band gap circuit, for converting a current memory state signal into a voltage memory state signal.

Preferably, the analog block further comprises an analog/digital (A/D) converter, for converting a voltage memory state signal into a digital memory state signal.

Preferably, the digital block further comprises a judge circuit, for making an evaluation to determine whether the received digital memory state signal fall within the range representing the memory is in good condition.

Preferably, the analog block further comprises a backscatter circuit, for transmitting the digital memory state signal to the reader by a means of backscattering.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1 is a schematic diagram showing a conventional RFID tag.

FIG. 2 is a schematic view of a RFID tag according to a preferred embodiment of the present invention.

FIG. 3 is a functional block diagram depicting the circuitry of a RFID tag according to the present invention.

FIG. 4 is a flow chart depicting a testing method according to the present invention.

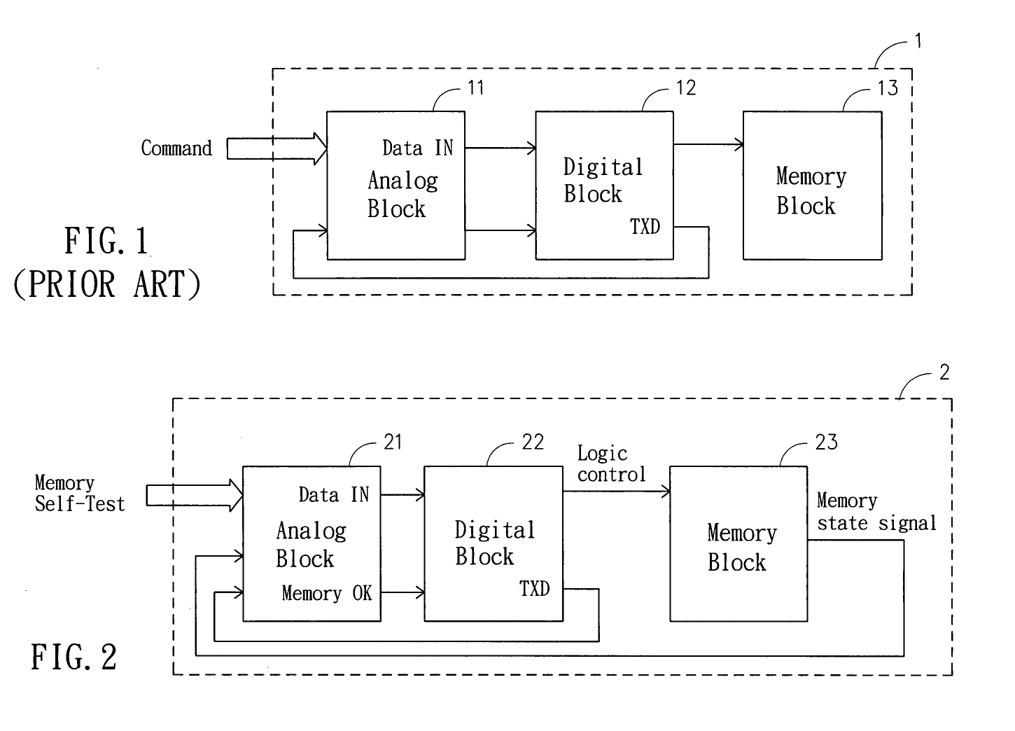

### DESCRIPTION OF THE PREFERRED EMBODIMENT

For your esteemed members of reviewing committee to further understand and recognize the fulfilled functions and structural characteristics of the invention, several preferable embodiments cooperating with detailed description are presented as the follows.

Please refer to FIG. 2, which is a schematic view of a RFID tag according to a preferred embodiment of the present invention. The RFID tag 2 of FIG. 2 is comprised of an analog block 21, a digital block 22 and a memory block 23. Wherein, the memory block 23 is capable of issuing a memory state signal to the analog block 21 for enabling the analog block 21 to generate a signal of “Memory OK” to the digital block 22 from a status pin of the analog block 21. As soon the digital block 22 receives the signal transmitted form the status pin, an evaluation is being made by the circuit embedded inside the digital block 22 for determine whether the memory block is working normally and then issuing a response signal from the TXD of the digital block 22 back to the analog block 21, and thereafter, the response signal is being send to a reader by the analog block 21.

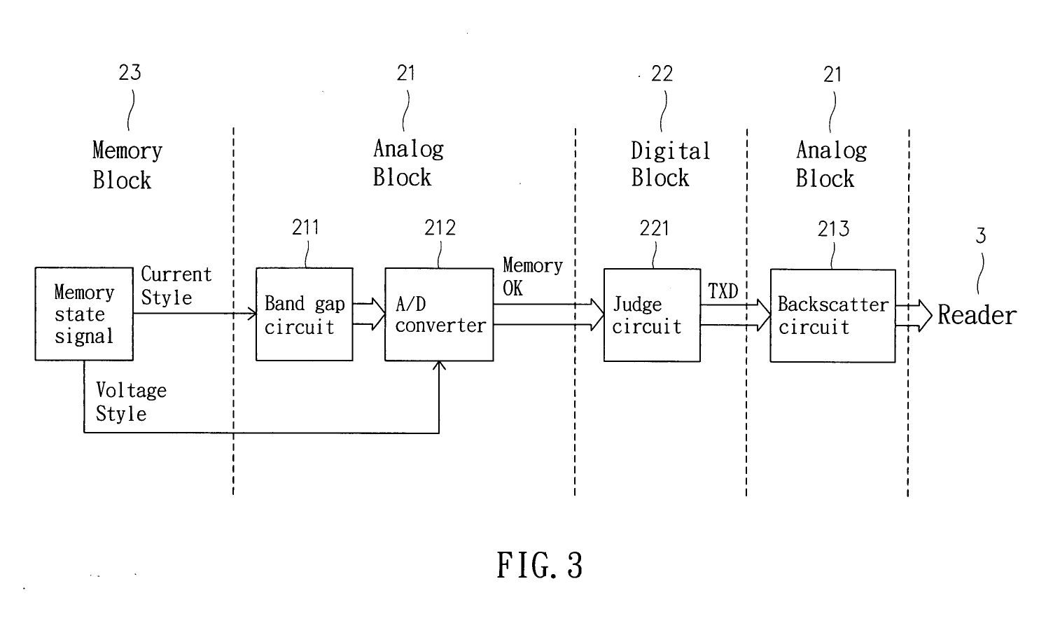

In order to enable the digital block 22 to embedded with desired memory testing scheme, circuits of specific functions must be added in the RFID tag 2. Please refer to FIG. 3, which is a functional block diagram depicting the circuitry of a RFID tag according to the present invention. Assuming the memory state signal issued by the memory block 23 can be a current memory state signal or a voltage memory state signal, it is preferred to integrate a band gap circuit 211 and an analog/digital (A/D) converter 212 inside the analog block 21 so that a current memory state signal issued from the memory block 23 can be converted into a voltage memory state signal by the band gap circuit, whereas the voltage memory state signal is transmitted to the A/D converter 212 to be further converted into a digital memory state signal to be transmitted to the digital block 22. Moreover, the digital block 22 further comprises a judge circuit 221, being used for make an evaluation to determine whether the received digital memory state signal fall within the range representing the memory is in good condition and then transmitting the response signal to the analog block 21 through the TXD of the digital block 2. Furthermore, the analog block 21 is comprised of a backscatter circuit 213 for providing a means of backscattering to be used for transmitting the received response signal to the reader 3 for enabling the same to aware whether the memory is working normally.

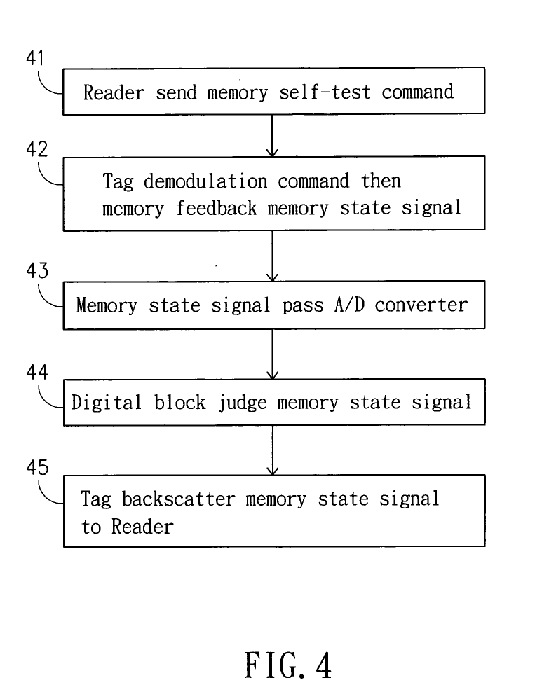

By the RFID tag embedded with memory testing scheme as describe above, a method for testing a RFID tag can be provided as shown in FIG. 4, which comprises steps of:
step 41: enabling the RFID tag to receive a memory self-test signal issued by a reader;
step 42: using the analog block to demodulate the received memory self-test signal so as to drive the memory block to issue a non-digital memory state signal;
step 43: using the analog block to convert the non-digital memory state signal, being a voltage signal, into a digital memory state signal;
step 44: using the digital block to make an evaluation for determining whether the received digital memory state signal fall within the range representing the memory is in good condition; and
step 45: transmitting the evaluation to the reader by the RFID tag.

Accordingly, if the evaluation resulting from the memory state signal indicates that the memory is working normally, the reader is going to proceed with a posterior process; otherwise, i.e. the memory is damaged, the reader is stop from processing any posterior process. It is noted that the RFID tag used in the present invention can be an active/semi-active read/write RFID tag or a passive read/write RFID tag.

By using a RFID tag equipped with a memory block capable of issuing a memory state signal, and as the memory state signal is first being converted into a digital signal to be received by the digital block for enabling the same to make an evaluation for determining whether the received digital memory state signal fall within the range representing the memory is in good condition and then transmitting the evaluation to the analog block, the reader is able to select a posterior process to be perform according to the evaluation transmitted from the analog block of the RFID tag such that the state regarding to whether the memory of a RFID tag is damaged can be acquired prior to assessing data from or writing data into the memory of the RFID tag.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A radio frequency identification (RFID) tag with embedded memory testing scheme, comprising:
a memory block, for issuing a non-digital memory state signal;
a digital block, for making an evaluation upon the memory state signal so as to generate a response signal according to the evaluation; and
an analog block; wherein, for receiving and demodulating the non-digital memory self-test signal while converting the non-digital memory self-test signal into a digital memory self-test signal to be received by the digital block, and for receiving the response signal and then transmitting the same to a reader.

2. The RFID tag of claim 1, wherein the RFID tag is a device selected from the group consisting of an active/semi-active read/write RFID tag and a passive read/write RFID tag.

3. The RFID tag of claim 1, wherein the memory self-test signal received by the analog block is issued by the reader.

4. The RFID tag of claim 1, wherein the memory state signal issued by the memory block is a signal selected from the group consisting of a current signal and a voltage signal.

5. The RFID tag of claim 1, wherein the analog block further comprises a band gap circuit, for converting a current memory state signal into a voltage memory state signal.

6. The RFID tag of claim 1, wherein the analog block further comprises an analog/digital (A/D) converter, for converting a voltage memory state signal into a digital memory state signal.

7. The RFID tag of claim 1, wherein the digital block further comprises a judge circuit, for making an evaluation to determine whether the received digital memory state signal fall within the range representing the memory is in good condition.

8. The RFID tag of claim 1, wherein the analog block further comprises a backscatter circuit, for transmitting the digital memory state signal to the reader by a means of backscattering.

9. A method for testing a testing a RFID tag with embedded memory testing scheme, comprising steps of:
(a) providing a RFID tag comprising an analog block, a digital block and a memory block;
(b) enabling the RFID tag to receive a memory self-test signal;
(c) using the analog block to demodulate the received memory self-test signal so as to drive the memory block to issue a non-digital memory state signal;
(d) using the analog block to convert the non-digital memory state signal, being a voltage signal, into a digital memory state signal;
(e) using the digital block to make an evaluation for determining whether the received digital memory state signal fall within the range representing the memory is in good condition; and
(f) transmitting the evaluation to a reader by the RFID tag.

10. The method of claim 9, wherein the RFID tag is a device selected from the group consisting of an active/semi-active read/write RFID tag and a passive read/write RFID tag.

11. The method of claim 9, wherein the memory self-test signal received by the analog block is issued by the reader.

12. The method of claim 9, wherein the memory state signal issued by the memory block is a signal selected from the group consisting of a current signal and a voltage signal.

13. The method of claim 9, wherein the analog block further comprises a band gap circuit, for converting a current memory state signal into a voltage memory state signal.

14. The method of claim 9, wherein the analog block further comprises an analog/digital (A/D) converter, for converting a voltage memory state signal into a digital memory state signal

15. The method of claim 9, wherein the digital block further comprises a judge circuit, for making an evaluation to determine whether the received digital memory state signal fall within the range representing the memory is in good condition.

16. The method of claim 9, wherein the analog block further comprises a backscatter circuit, for transmitting the digital memory state signal to the reader by a means of backscattering.
